(19) United States
(12) Patent Application Publication
(10) Pub. No.: US 2003/0183418 A1
(43) Pub. Date: Oct. 2, 2003

(54) Electrical circuit and method of formation

(76) Inventors: Abram M. Castro, Fort Worth, TX (US); Bernardo Gallegos, The Colony, TX (US); Gary Lee Engvall, Lewisville, TX (US)

Correspondence Address: Philip G. Meyers, Philip G. Meyers Intellectual Property Law, P.C., Suite 302, 1009 Long Prairie Road, Flower Mound, TX, 75022, US

(21) Appl. No.: 10/457,129

(22) Filed: Jun. 9, 2003

Related U.S. Application Data
(62) Division of application No. 09/973,294, filed on Oct. 9, 2001.

(51) Int. Cl. H01L 23/34; H01L 23/42; H05K 1/16

(52) U.S. Cl. 174/260; 257/706; 257/720; 257/713

(57) ABSTRACT

A circuit board according to the invention is made from two or more laminates each made of a fusible dielectric material, which laminates are bonded to each other along respective inner faces thereof. Each such laminate is preferably a pre-preg sheet containing both a heat-fusible resin and a reinforcing fiber filler to provide the desired stiffness and strength. A number of first electrical contacts are exposed on an outer face of the first laminate, and second electrical contacts are exposed on an outer face of the second laminate. The circuit board further includes a plurality of electrical conductors each running from a first contact to a second contact, the conductors including elongated conductive lines extending along one of the first or second laminates, and vias extending through the first and second laminates which have been filled with an electrically conductive via filler.

This application is a divisional of U.S. patent application Ser. No. 09/973,294, filed Oct. 9, 2001.

### TECHNICAL FIELD

The present invention relates to circuit boards and integrated circuit packages and, more particularly, to method for making electrical circuits on circuit boards or integrated circuit packages.

### BACKGROUND OF THE INVENTION

Semiconductor chip package designs have had difficulty keeping pace with ever-increasing chip frequencies and industry demands for higher circuit densities at reduced cost. Castro et al U.S. Pat. Nos. 6,107,683 and 6,248,612 describe a substrate package wherein the circuit is built up upon a copper heat sink, the integrated circuit (IC) die is mounted in a face up in a central cavity, and wires are used to interconnect the package bond pads with the die. This type of chip package has proven reliable, but requires wire bonding and a copper plate as a support. Substrate packages built on a copper heat sink are generally more expensive to make than ones formed on commonly available heat-curable pre-preg materials, wherein plastic or glass fibers are disposed in a resin matrix that can be cured by heating. However, pre-preg materials do not have the rigidity of metal plates and are difficult to laminate to one another in a manner that maintains a highly accurate registration between interconnects called for by the circuit design. The present invention addresses this limitation.

Flip chip substrate packages do away with the need for wire bonding by connecting the IC die directly to contacts formed on the substrate package. This is occasionally done in a “die down” configuration wherein the die pads and the bond pads for the solder balls are on the same side of the copper heat sink, and it is generally necessary to mill a cavity in the center of the heat sink to fit the die, or to build up circuit layers around a central die space.

Die-up flip chip carriers are used in a majority of applications wherein the die is mounted on one side of the support and the solder balls for connection to a circuit board are on the opposite side. See, for example, U.S. Pat. No. 6,229,209 (Matsushita). Conductive interconnects must be provided through the thickness of the support, which in the '209 patent is a single glass-ceramic circuit board. However, the described carrier, showing only a single support, is of limited utility as compared to multilayer chip packages known in the art.

Ormet Corporation has introduced a family of transient liquid phase sintering conductive adhesives which can be used to form electrical interconnects. See U.S. Pat. Nos. 5,716,663, 5,376,403, 5,853,622 and 5,922,397. The paste mixture when sintered creates intermetallic compounds from metal powders that provide an interconnect with good thermal, mechanical and electrical properties. These materials have nonetheless found limited application as compared to solder, plating through holes and other conventional interconnect materials. The present invention provides a new use for such sinterable, electrically conductive adhesive materials.

### SUMMARY OF THE INVENTION

A circuit board according to the invention is made from two or more laminates each made of a fusible dielectric material, which laminates are bonded to each other along respective inner faces thereof. Each such laminate is preferably a reinforced polymer system such as a thin pre-preg sheet containing both a heat-fusible resin and a reinforcing fiber filler to provide the desired stiffness and strength, or may be a layer of reinforced polymer that is formed in situ, such as by spraying. If there are three or more laminates, the first and second laminates are the ones disposed on the outside. A number of first electrical contacts are exposed on an outer face of the first laminate, and second electrical contacts are exposed on an outer face of the second laminate. The circuit board further includes a plurality of electrical conductors each running from a first contact to a second contact, the conductors including elongated conductive lines extending along one or both of the first or second laminates and vias extending through the first and second laminates which have been filled with an electrically conductive filler. For purposes of the invention, expressions such as “formed on” or “superposed on” mean do not require direct contact between the parts or layers referenced, unless so specified, and other components or layers may intervene.

In a preferred form of the invention, the first electrical contacts are configured as flip-chip die pads and the second electrical contacts are configured as solder ball bond pads in ball grid array (BGA) configuration, so that the circuit board can be used as a flip-chip integrated circuit package substrate. For this purpose, a preferred conductive filler consists essentially of an adhesive containing conductive metal particles, especially a transient liquid phase sintering conductive adhesive wherein the metal particles have been sintered after filling of the adhesive into the via, and the conductive lines consist essentially of a plated metal disposed between an outer surface of at least one of the first and second laminates and an external soldermask layer.

According to another aspect of the invention, some or all of the electrical conductors are embedded between a pair of fused laminates. In an IC package substrate, it is especially useful to make the substrate using three fused laminates, locating the power supply conductor and the ground conductor (which are larger than individual signal lines or conductors) between the first and third and second and third laminates respectively, and locate the signal lines on the outside of the first laminate, the outside of the third laminate, or both. This isolates the power and ground connections from the signal lines while permitting double density signal lines.

The invention also provides a process for making the foregoing circuit board or IC package substrate. Such a process includes a step of forming a first subassembly, wherein the first subassembly includes a first rigid support plate, a first laminate made of a fusible dielectric material bonded to the rigid support, and a first circuit pattern including a number of vias through the first laminate filled with an electrically conductive filler. A second subassembly of similar construction is formed, wherein the second subassembly includes a second rigid support plate, a second laminate made of a fusible dielectric material bonded to the rigid support, and a second circuit pattern including a number of vias through the second laminate filled with an electrically conductive filler. Vias in on inner surface of the first laminate are brought into electrical contact with the circuit pattern of the second laminate, and vias on an inner surface of the second laminate are brought into electrical contact with the circuit pattern of the first laminate. In some cases, as where the via penetrates straight through both laminates, two (or more) filled vias will be in alignment. In others, the filled vias will be offset from one another, with a conductive line or plane running between them as discussed hereafter. The inner surfaces of the first and second laminates are bonded together to form electrical connections at the filled vias, and the rigid supports are then removed from outer faces of the first and second laminates. Such a process permits more precise alignment of electrical interconnections, and the heat used to bond the laminates together can be used to cure the conductive filler.

In a preferred form of this process, the step of forming the first subassembly proceeds by forming a first release layer on a face of the first rigid support, forming a first electrically conductive metal layer on the release layer, placing a first laminate made of a dielectric material comprising fibers having a resin impregnated therein over the first release layer and first conductive layer, forming vias (preferably by laser drilling) through the first laminate at locations overlying the electrically conductive metal layer, and filling the vias in the first laminate with the electrically conductive filler material. Similarly, the second subassembly is made by forming a second release layer on a face of the second rigid support, forming a second electrically conductive metal layer on the second release layer, placing a second laminate made of a dielectric material comprising fibers having a resin impregnated therein over the second release layer and second conductive layer, forming vias through the second laminate at locations overlying the electrically conductive metal layer, and filling the vias in the second laminate with the electrically conductive filler material. The step of removing the rigid supports then proceeds by removing the first rigid support from the first release layer and removing the second rigid support from the second release layer, after which the release layers can be removed, leaving the surface circuit patterns exposed. Additional subassemblies can be interposed to provide additional circuit layers, for example, the embedded power and ground connections described above.

According to another aspect of the invention, a heat sink may be combined with a flip-chip integrated circuit package substrate of the invention to provide additional mechanical stiffness and thermal management. The heat sink is bonded to the outer face of the first laminate and has a central opening therein wherein the die pads are accessible. In a resulting, flip-chip integrated circuit package, a heat conductive material may be added to the encapsulant so that heat is more readily transferred from the die to the heat sink, which is spaced from the die.

More generally, a flip-chip integrated circuit package of the invention includes a substrate having a plurality of exposed die pads on a die side of the substrate, a plurality of exposed solder ball bond pads on an ball side of the substrate, and a plurality of electrical conductors each running from a die pad to a solder ball bond pad, the conductors including elongated conductive lines extending along the substrate and interconnects extending through the substrate. The substrate may be a layer structure using the laminates of the invention as described above, or a substrate of another type known in the art. A heat sink having a central opening therein is bonded to the die side of the substrate, so that the die pads are accessible through the central opening in the heat sink. An integrated circuit die is positioned in the central opening of the heat sink in contact with the die pads, and a layer of an encapsulant such as an epoxy resin surrounds the die, wherein the layer of an encapsulant contains a heat conducting material that conducts heat from the die to the heat sink better than the encapsulant by itself. For this purpose “encapsulant” means any flowable material that can be poured into a die cavity and then cured to a hard state, which encapsulant is electrically and thermally insulating. The heat conducting material may for example comprise metal particles distributed in the encapsulant between the die and the heat sink. These and other aspects of the invention are described further in the detailed description that follows.

### BRIEF DESCRIPTION OF THE DRAWINGS

A more complete understanding of the invention may be had by reference to the following detailed description when taken in conjunction with the accompanying drawings, wherein:

FIGS. 1 to 27 are a series of schematic sectional views, taken along the line of each circuit, illustrating the stages of making an integrated circuit package substrate according to the invention;

FIG. 28 is a partial (quarter) top view illustrating an integrated circuit package substrate made by the method of the invention as illustrated in FIGS. 1-27;

FIG. 29 is a schematic sectional view illustrating an embedded ground plane made by the method of the invention as illustrated in FIGS. 1-27;

FIG. 30 is a partial schematic sectional view illustrating an alternative embodiment of an integrated circuit package substrate according to the invention;

FIG. 31 is a schematic top view of the integrated circuit package of the embodiment of FIG. 30;

FIG. 32 is an enlarged view of the dotted area shown in FIG. 31;

FIG. 33 is a schematic bottom view of the integrated circuit package of the embodiment of FIG. 32;

FIG. 34 is an enlarged view of the dotted area shown in FIG. 33; and

FIG. 35 is a schematic diagram of a flip-chip integrated circuit package according to another embodiment of the invention.

### DETAILED DESCRIPTION

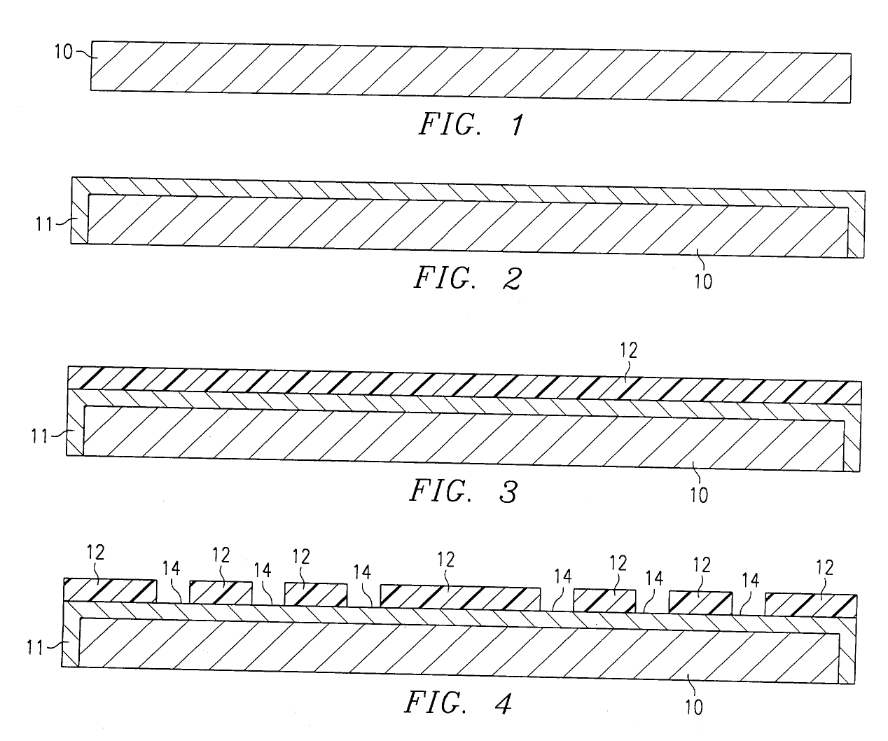

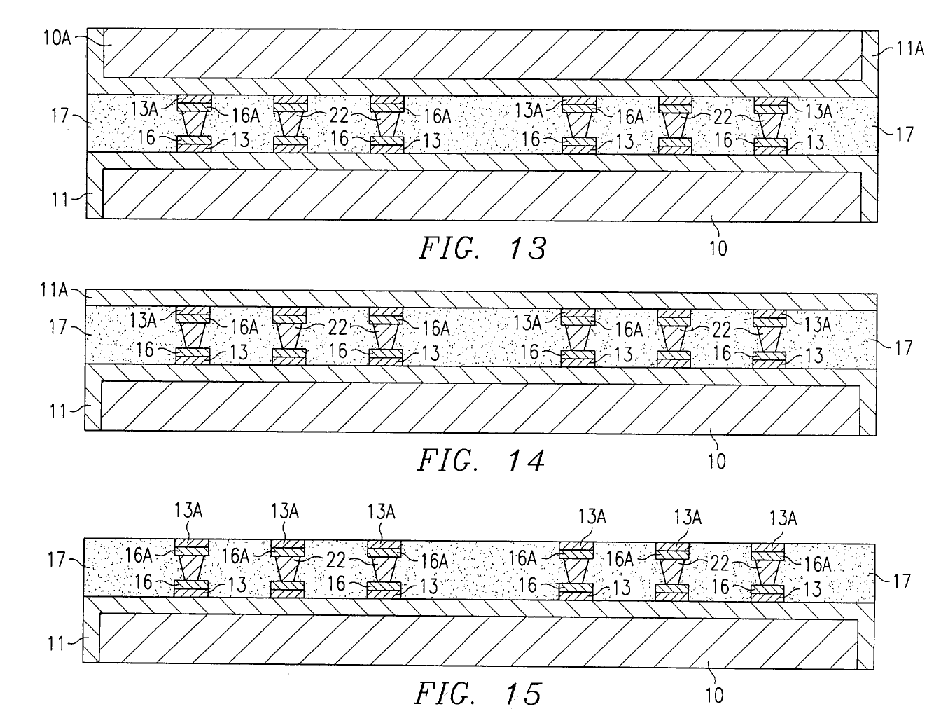

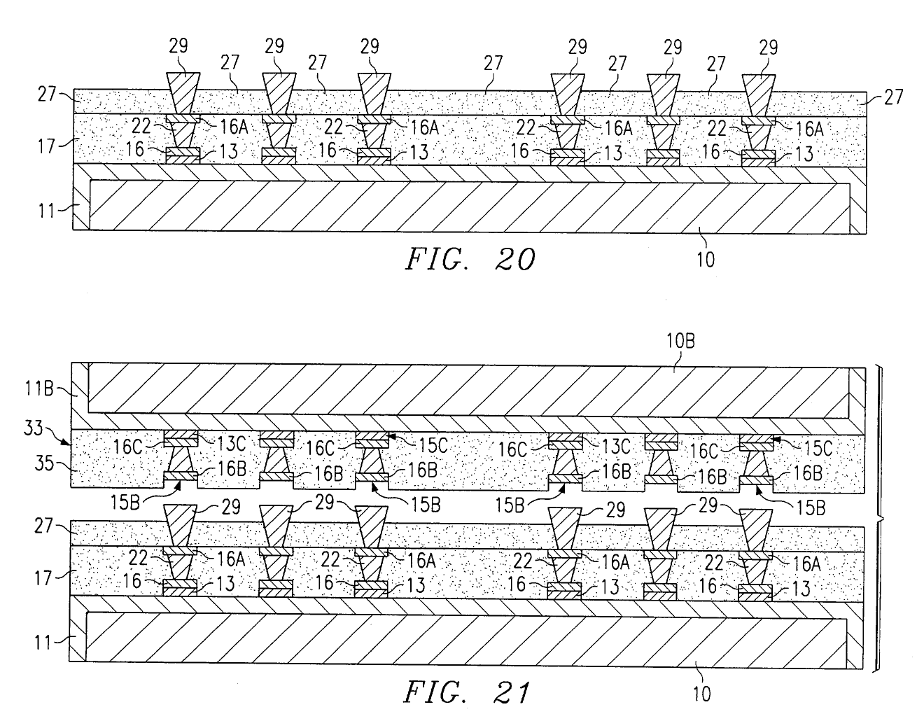

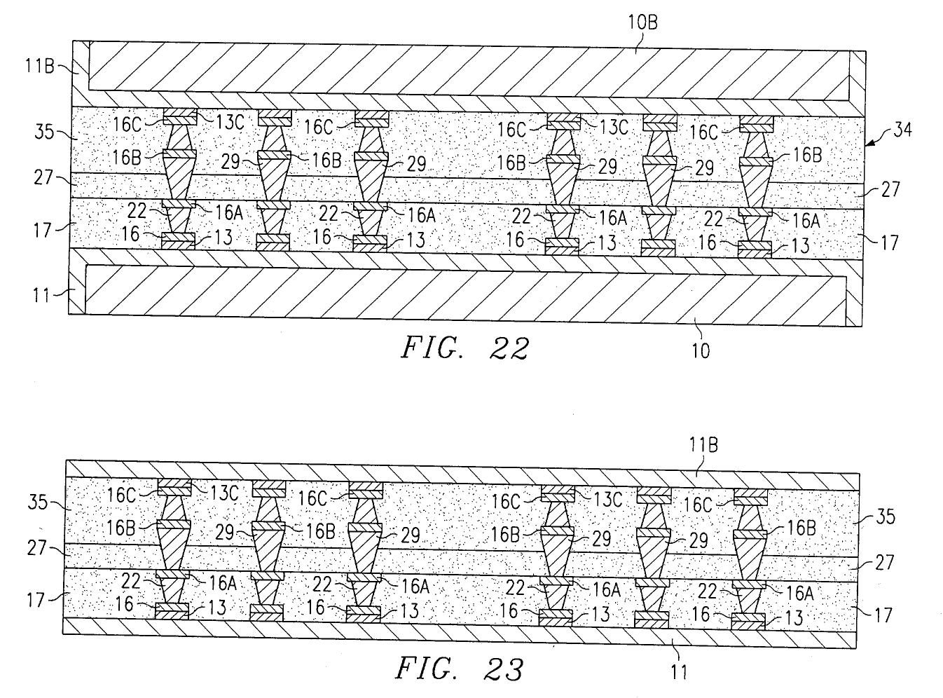

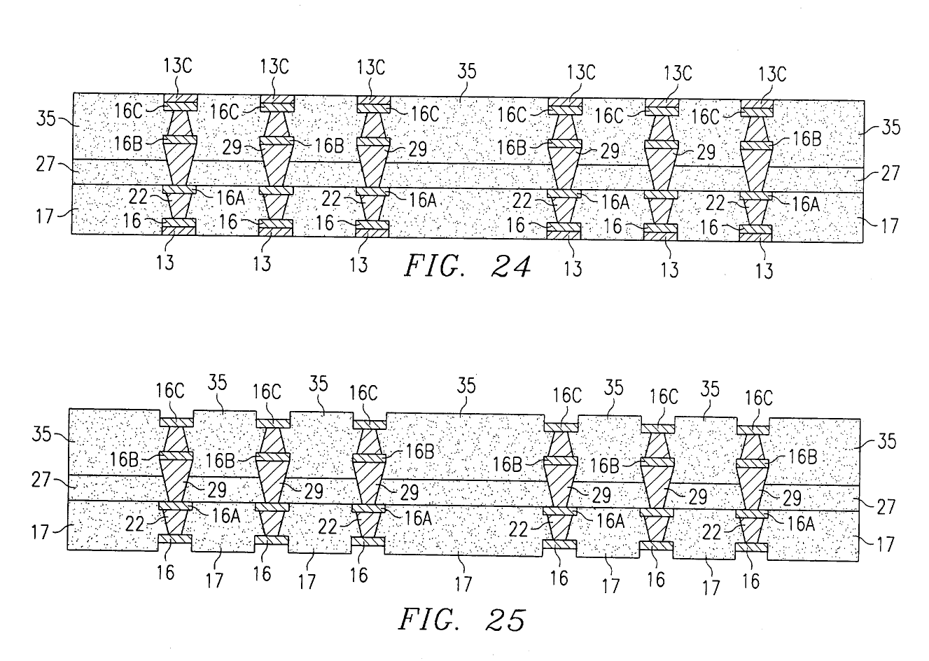

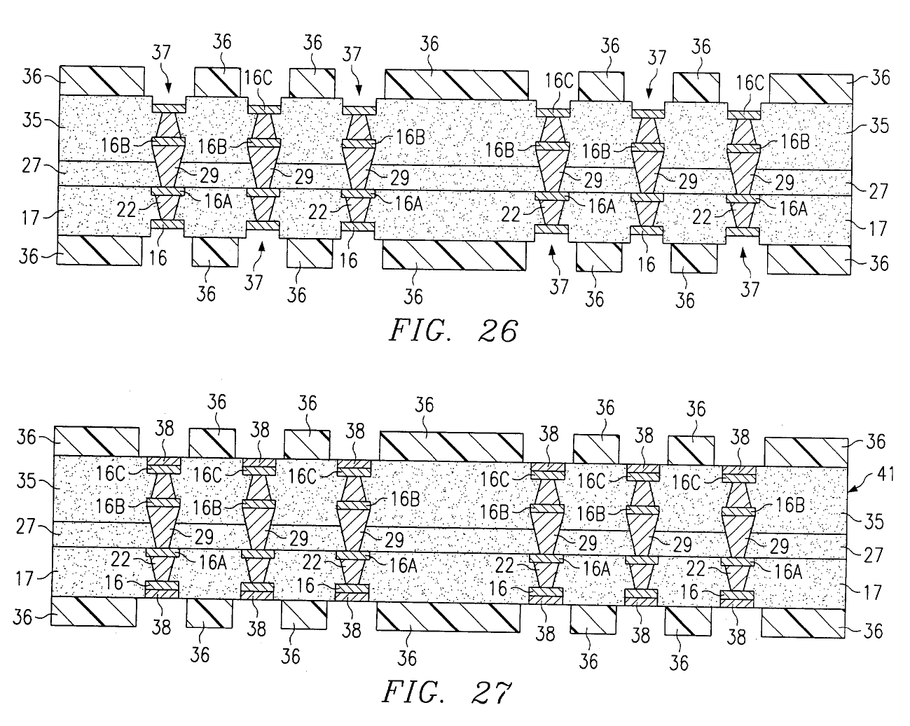

Referring first to FIGS. 1 to 27, a die-up, flip-chip integrated circuit package substrate according to the invention is made by a sequential build up that starts with a thin stainless steel plate 10 (0.062″ thick) that has been prepared by surface oxidation. Copper is flash plated to steel plate 10 as shown in FIG. 2 to form a thin (e.g., 10-20 micron, especially 15 micron) copper layer 11. The adhesion of the copper layer 11 to plate 10 is relatively weak, such that plate 10 can be pulled off later. A thicker layer 12 of dry film dielectric photoresist, such as a polyclad aqueous photodevelopable resist, is coated onto layer 11 and a pattern is developed therein in a manner well known in the art. This pattern preferably corresponds to the locations of electrical contacts to be located on the outside of the finished IC package. An optional second conductive metal 13 such as tin is flashed into the resulting channels 14, then flashed over with a thin layer (e.g., 3 microns) of copper, followed by plating to form a copper layer 16 in accordance with the location of the electrical contacts. The second metal layer 13 is applied for purposes of the manufacturing process as described hereafter but forms no part of the finished substrate. The resist layer 12 is then stripped by conventional methods, leaving the plate with copper layer 11, and a first circuit pattern 15 of including tin and copper layers 13, 16.

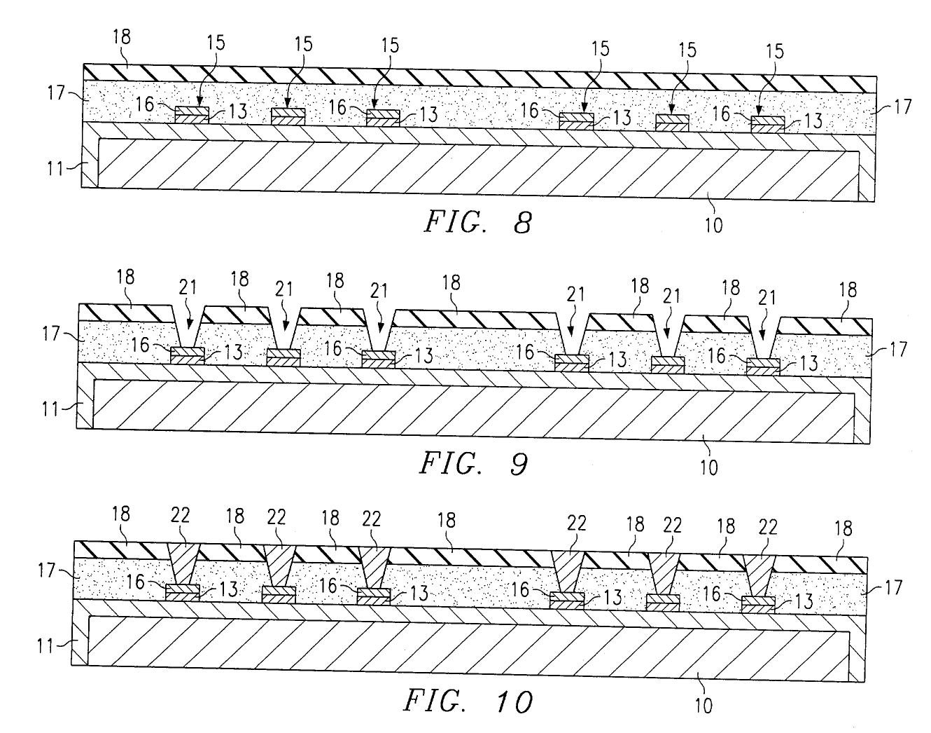

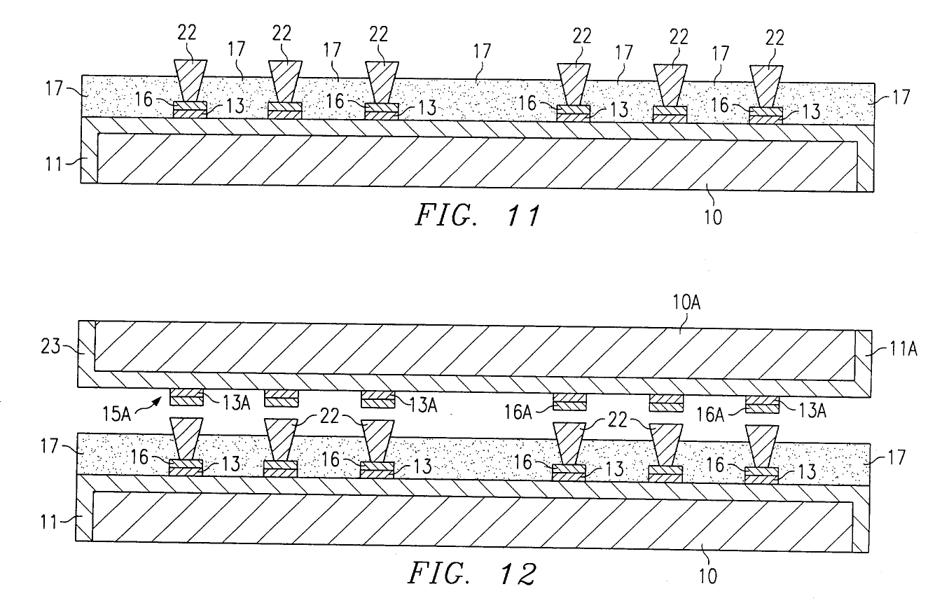

A resin-impregnated fiber laminate 17, known commercially as pre-preg, is then applied with a light tack to the back of the assembly as shown in FIG. 8. An aramid-fiber epoxy pre-preg laminate 17 is preferred. As shown, the resin of laminate 17 flows and embeds circuit pattern 15 on three sides. A laser such as an ESI 5200 YAG laser or Hitachi CO₂ laser is then used at a power level sufficient to burn through the beta-stage pre-preg laminate 17 but not sufficient to burn through the underlying copper. Holes or vias 21 are drilled at the location of each interconnect required by the circuit design. A conductive paste 22 of resin and conductive metal powder is then filled into holes 21. As paste 22, a sinterable material available commercially as Ormalink made by Ormet Corporation is preferred. Other preferred materials are described in U.S. Pat. Nos. 5,716,663, 5,376,403, 5,853,622 and 5,922,397, the contents of which are incorporated by reference herein. Ormalink contains copper powder in a resin base. The heat supplied during the fusing of one pre-preg laminate to another as described hereafter is effective to sinter the metal particles in the conductive adhesive to achieve electrical conductivity.

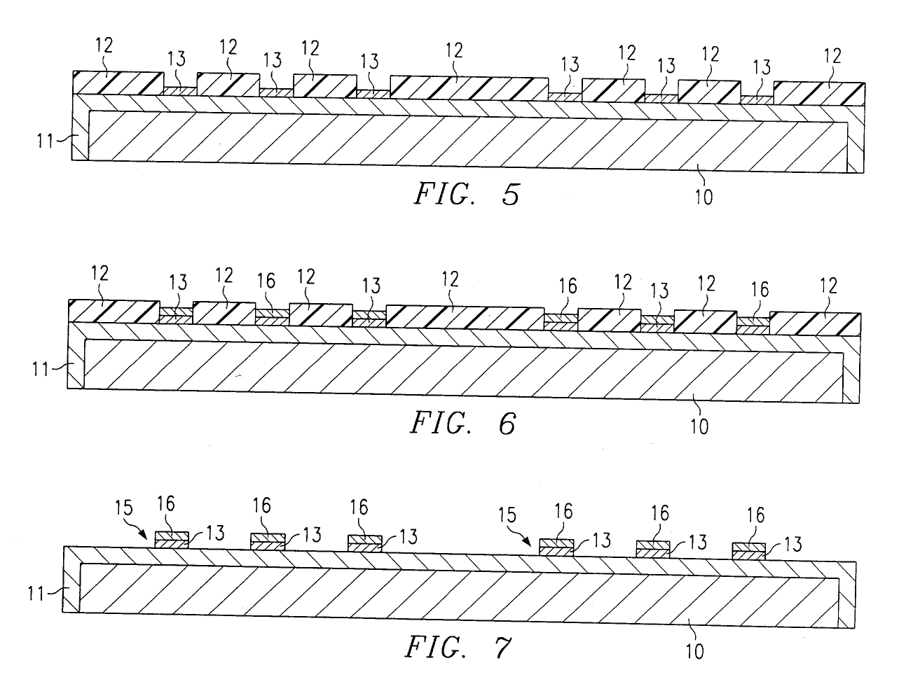

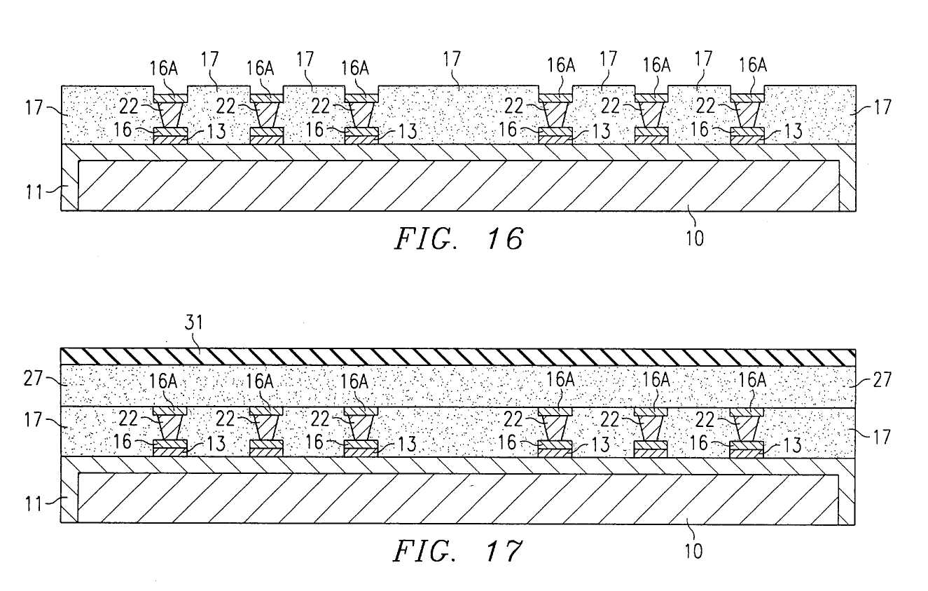

After filling of vias 21, the mylar release liner 18 of laminate 17 is peeled off, and a steel plate assembly 23 having a steel plate 10A, copper coating 11A, and tin and copper layers 13A, 16A forming a second circuit pattern 15A thereon is inverted and positioned over filled vias 21 (FIG. 12). Assembly 23 may be made in the same manner as described leading up to FIG. 7, but with a different circuit design. Assembly 23 is pressed into face-to-face contact with the underlying layers so that connection points of copper layers 16A contact and bond to the exposed tops of the filling material 22, which forms a conductive pathway through to the underlying circuit pattern 15. This is carried out with a circuit press known in the art that uses multiline tooling to precisely align the assembly.

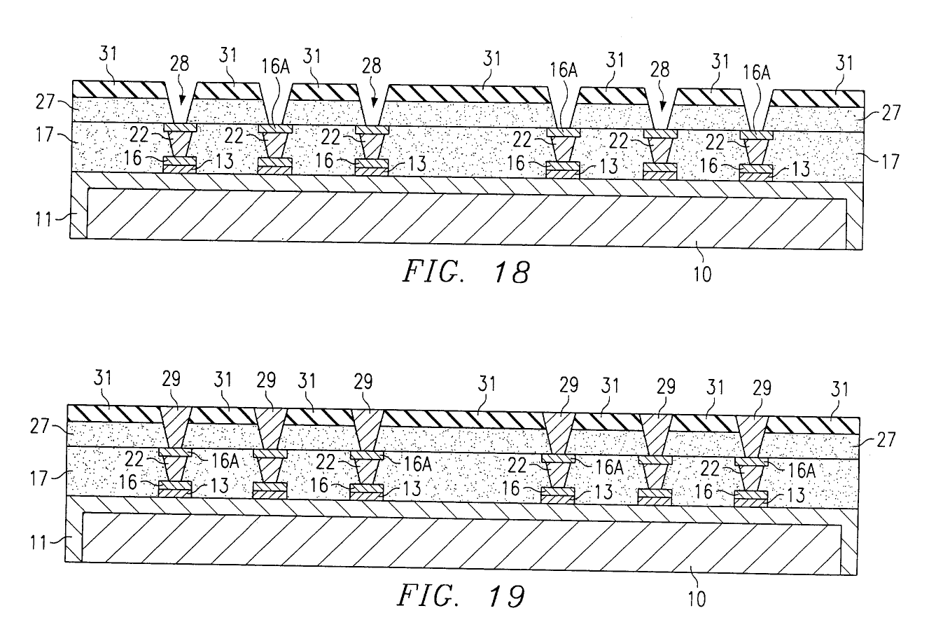

Steel plate 10A is then removed by means of the weak adhesion between plate 10A and copper layer 11A, and layer 11A is then removed by flash copper etching (FIG. 15), leaving layers 13A, 16A intact to form circuit pattern 15A superposed on the contact pattern 15. Tin layer 13A (if applied) is then electrolytically stripped, leaving copper layer 16A exposed. In the alternative, if the etching of a thin outer copper layer such as 11 or 11A can be precisely controlled, the intervening tin layer 13, 13A, etc. can be omitted, and the outer copper layer removed without stripping the underlying copper circuit layer. A second piece of pre-preg laminate 27 is placed over copper layer 16A, resin side down, embedding copper layer 16A as shown in FIG. 17. A second set of vias 28 are then drilled through laminate 27 at desired interconnect points, the laser again being stopped by the underlying copper. Additional conductive paste 29 such as Ormalink is filled into vias 28, and the outer pre-preg liner 31 is removed. For the sake of uniformity, each of the pre-preg laminates used are preferably identical in type and dimensions.

The resulting structure is now ready for final pairing. A second circuit assembly 33 is prepared having the same layer structure as shown in FIG. 16 except for differences in the specific circuit pattern. Assembly 33 is formed with second and third circuit patterns 15B and 15C on opposite sides of a third pre-preg laminate 35. Assembly 33 is inverted and brought into precise alignment with the underlying structure so that contact portions of copper layer 16B of assembly 33 are brought into registration with the filler material 29 in vias 28 (FIG. 22). The respective steel plates 10, 10B and copper release layers 11, 11B are then successively removed from opposite sides of the resulting paired assembly 34, leaving the optional tin layers 13, 13C exposed. Copper layers 11, 11B can be removed using a chemical copper etchant which does not remove the underlying tin. These tin layers 13, 13C are then electrolytically stripped in the same manner as layer 13A, leaving copper layers 16, 16C exposed. A soldermask layer 36 is then applied to both sides, then imaged and developed to expose desired contact points 37 on opposite sides of the assembly. The contacts 37 are then surface finished with a precious metal 38 such as silver, resulting in a circuit board substrate 41 having the structure shown in FIG. 27.

In this example four circuit layers 15, 15A, 15B and 15C are formed, with 15 and 15C being disposed on the outside beneath soldermask layers 36, and circuits 15A, 15B being disposed on the inside, embedded between the associated pieces of pre-preg which have been fused together. To minimize the number of holes laser drilled through the pre-preg, it is preferred to run the signal lines along the opposite outer sides of the assembly as circuits 15, 15C. Circuits 15A and 15B are preferably designed as power and ground planes, respectively. These planes are larger (wider, more planar) in comparison with the signal lines, and embedding them inside the pre-preg laminate isolates them from each other and the signal lines.

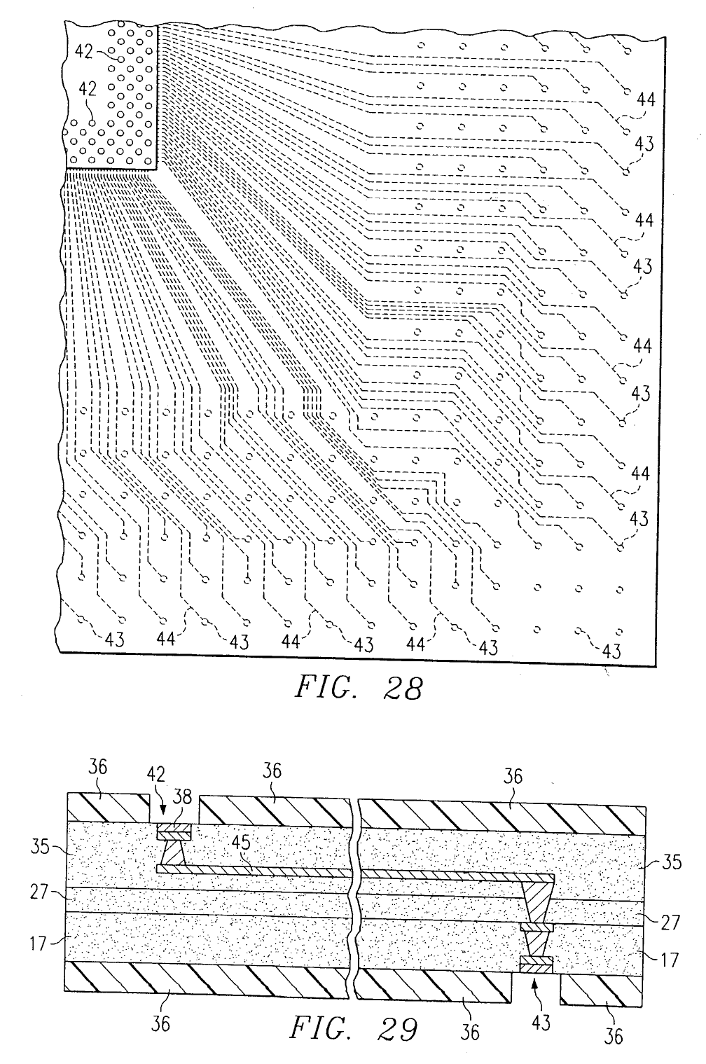

Die pads 42 on one side for flip-chip die attachment as well as an outer row or rows of solder ball pads 43 on the other side, are each connected by a conductive line 44 of one of circuits 15 or 15C (lines 44 on both sides of the substrate are shown in FIG. 28 for purposes of illustration.) FIG. 29 illustrates a ground plane 45 with current passing through the sintered conductive paste material in the vias when moving between a plane 45 and a pad 42 or 43. Solder ball pads 43 may be given an OSP, silver or tin finish, and die pad pads 42 may have a copper/OSP or solder finish. Connections for lines 44 are similar, except that a single via including three stacked “cones” of conductive filler material penetrates the entire thickness of the assembly, either at the location of pad 42 or 43.

If desired, the intermediate steps used to form the intermediate circuit 15A can be omitted (from FIGS. 12 to 20). In such a case the ground and power planes could be formed at offset locations in the same embedded circuit layer. Similarly, the procedure shown in FIGS. 12-20 may be repeated if needed to build in more than two embedded circuit layers. In addition, vias may be provided and filled for conducting heat away from the die, if needed.

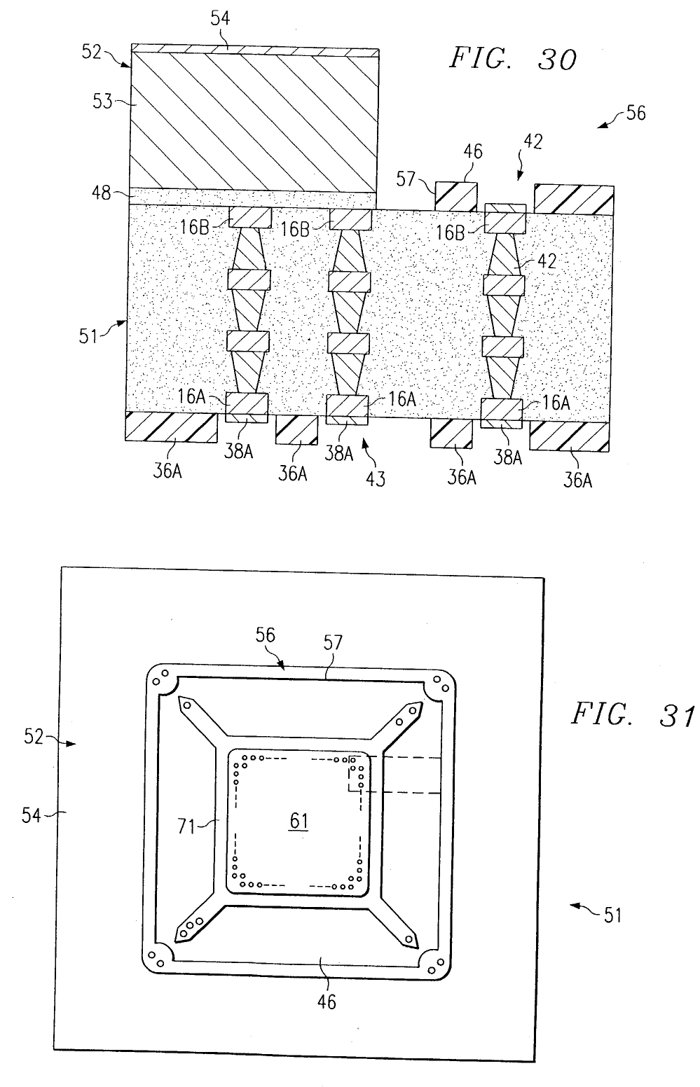

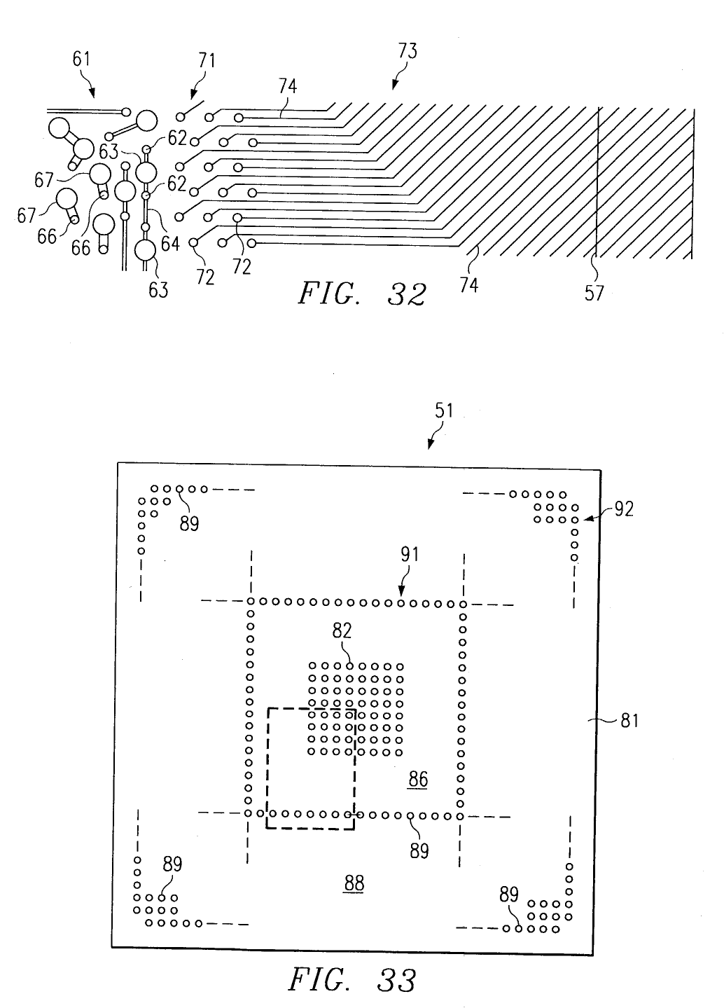

FIGS. 30-34 illustrate an alternative embodiment of a IC package substrate 51 of the invention which may have substantially the same layer structure as described for substrate 41. However, a soldermask layer 46 on the die side is reduced in size (length and width), so that a square or rectangular heat sink 52, which also acts as a stiffener for the assembly, can been adhered to one side of the layer structure by an adhesive or direct bonding, preferably by means of a layer 48 of a low cure adhesive that minimizes mechanical stress, such as of the Tovay YEF series. Heat sink 52 includes a relatively thick copper plate clad 53 with an outer finish layer 54 such as nickel. A square central opening 56 forms a die cavity. Soldermask 46 may optionally be slightly set back from the inner edge of heat sink 52, following boundary 57 as shown in FIG. 31. Exposed surfaces of signal lines in this area are covered later during encapsulation of the die.

A central area 61 of the die side, which area 61 will underlie the die when installed and is of smaller length and width than the die, is configured with an array of power and ground pads 62 which are connected back to enlarged, depthwise interconnects 63 by conductive lines 64. Lines 64 often connect together several pads 62 and interconnects 63. Pads 62 are generally arranged at regular intervals, and are positioned according to the die manufacturer's requirements. Central area 61 also includes a number of signal pads 66 which have associated interconnects 67. A square peripheral area 71 surrounding central area 61 contains exposed signal pads 72 which connect directly to rows of pins along the periphery of the die. A further square area 73 surrounding area 71 contains signal lines 74 which run from pads 72 towards the periphery of the device, disappearing beneath the inner edge of heat sink 52, and then penetrating through the thickness of the device to ball pads 89 on the opposite side.

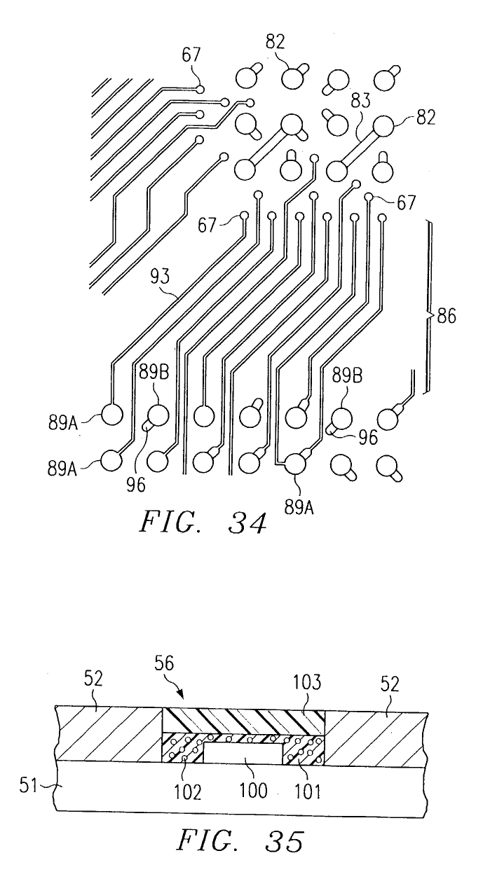

As shown in FIGS. 33-34, the solder ball side 81 of the substrate 51 includes a central group of ball pads 82 (8 by 8 in this example) for power and ground connections which are connected back to interconnects 63 and power and ground pads 62 on the die side. Some of these may be joined by conductive lines 83 if it is necessary to reposition a ball pad location. Surrounding pads 82 is a square central area 86 free of pads through which conductive lines 93 on the ball side run, and around area 86 is a square outer area 88 in which a large number of signal ball pads 89 are positioned. These are generally arranged in rows and columns, in this example, nine pads deep on each side, with an innermost row 91 being 18 by 18 pads and the outermost row 92 being 34 by 34 pads, less pads omitted on the four corners. As shown in FIG. 34, some of the outer ball pads 89A are connected by means of conductive lines 93 disposed just beneath the associated soldermask layer to depthwise interconnects 67 positioned near and among the central ball pads 82, whereby pads 89A are electrically connected to signal pads 66 on the die side. Other pads 89B have adjacent interconnects 96 that emerge underneath heat sink 52 and connect to each of lines 74 on the opposite side, leading to the outer signal pads 72.

It is most convenient to locate the power and ground pads on the side of the substrate directly opposite the die connections, but of course such connections could be routed to the side in the same manner as the signal connections. Similarly, having conductive lines 74, 93 on both sides of the device permits up to double the number of signal connections at a given spacing as compared to a single-sided construction. The foregoing embodiments also conserve space by vertical stacking of vias to form the interconnects. Conventional manufacturing methods with less precise registration between adjacent layers generally require use of offset vias, greatly increasing the amount of space required. A substrate according to the invention can save up to 50% in required space as compared to a conventional package substrate with the same number of connections.

Once formation is complete, a circuit board substrate 41 or 51 of the invention is singulated, tested, inspected and packed for shipment. Final processing is carried out by the end user, who applies the die to the die pads and solder balls to the solder ball pads, then encapsulates the die in the conventional manner to form the finished integrated circuit package. Such a circuit board substrate according to the invention provides numerous advantages over other known IC package designs. The flip-chip die connection eliminates the expense of connecting bonded wires and avoids the need to form a cavity for the die. The invention further provides a highly effective technique for forming conductive vias and achieving registration of fine features such as electrical contact points during the production process even when a large number of substrates are formed at the same time as a panel and later singulated by cutting. The use of bonded pre-preg laminates makes circuit board substrate 41 highly cost effective as compared to substrate packages requiring milled copper supports/heat sinks.

The invention permits fine resolution of small features. For example, a substrate of dimensions 35 by 35 mm with a minimum line width and line spacing of 35 microns can accommodate an I/O count of 816, bump pad diameter 125 microns, via pad diameter 90 microns, signal capture pad diameter 125 microns, signal via diameter 90 microns, staggered bump pad pitch 160 microns, solder ball pitch of 1.00 mm, with 2 signal layers and 2 power/ground layers. The filled vias, due to the laser used to burn the vias, tend to be conical, for example, 90 microns diameter on the outside, 75 microns diameter on the inside, with a depth of about 80 microns (equals the thickness of the surrounding dielectric layer.) The sinterable conductive paste material, once sintering occurs, forms a conductive network of metal particles that is highly effective for conducting current. In subsequent sintering cycles, as needed when the second or subsequent pre-preg laminates are added, the previously sintered material in the vias does not re-melt and retains its superior electrical conductivity.

The method of the invention keeps each half of a laminate pair bonded to a rigid backing or support (the steel plate) during assembly. This provides an enormous advantage in obtaining accurate registration of interconnections that cannot be matched by attempting to laminate a piece of pre-preg or adhesive tape onto a circuitized piece of pre-preg. Both halves of the assembly should be rigidly secured to the support during pairing to ensure a superior product.

According to a further aspect of the invention, the end user encapsulates the die in a novel manner in order to maximize heat dissipation through the heat sink. Unlike in other formation processes where the die is mounted adjacent to the core or heat sink, in the present invention the die 100 as shown in FIG. 35 is spaced from the heat sink 52. The encapsulant used to cover the die is typically an epoxy that is non-conductive of both heat and electricity. According to a further aspect of the present invention, the die is placed in contact with a heat-conductive bridge that conducts heat from the die to the heat sink to a degree substantially better than a conventional encapsulant. This could be done, as shown in FIG. 35, by use of a layer 101 of an encapsulant having heat-conductive filler particles 102 distributed therein (e.g., aluminum or the like) surrounding die 100 which would improve the heat conductivity to the heat sink 52 preferably without creating any electrical conductivity. A further layer 103 of conventional encapsulant lacking the conductive filler 102 may be filled in over layer 101 if needed. Such an arrangement may become essential as integrated circuits are designed to operate at ever-increasing speeds.

The heat conductive bridge is not limited to the filler particles 102 shown. For example, after the space around the die is filled with encapsulant to the level of the die, a backing plate made of copper, similar to the heat sink itself, can be inserted like a lid behind the die 100. The backing plate has the same length and/or width as recess 56 and thereby acts as a heat bridge. A further layer of encapsulant is filled in behind the heat conductive plate, which could be perforated or cut-away (e.g., X-shaped) so that the encapsulant could be filled in both above and below in one step after placement of the plate.

The invention described herein is not limited to the applications described above and can be used for making circuit boards other than those for mounting an IC die. While the invention has been described with reference to the illustrated embodiment, it is not intended to limit the invention but, on the contrary, it is intended to cover such alternatives, modifications and equivalents as may be included in the spirit and scope of the invention.

1. A process for making a circuit board, comprising:
forming a first subassembly, wherein the first subassembly includes a first rigid support plate, a first laminate made of a fusible dielectric material bonded to the rigid support, and a first circuit pattern including a number of vias through the first laminate filled with an electrically conductive filler;
forming a second subassembly, wherein the second subassembly includes a second rigid support plate, a second laminate made of a fusible dielectric material bonded to the rigid support, and a second circuit pattern including a number of vias through the second laminate filled with an electrically conductive filler, wherein vias in an inner surface of the first laminate can be brought into electrical contact with the circuit pattern of the second laminate, and vias in an inner surface of the second laminate can be brought into electrical contact with the circuit pattern of the first laminate;
bonding the inner surfaces of the first and second laminates together to form electrical connections at the aligned filled vias; and
removing the rigid supports from outer faces of the first and second laminates.

2. The process of claim 1, wherein the step of forming the first subassembly comprises:
forming a first release layer on a face of the first rigid support;
forming a first electrically conductive metal layer on the release layer;
placing a first laminate made of a dielectric material comprising fibers having a resin impregnated therein over the first release layer and first conductive layer;
forming vias through the first laminate at locations overlying the electrically conductive metal layer; and
filling the vias in the first laminate with an electrically conductive filler material.

3. The process of claim 1, wherein the step of forming the second subassembly comprises:
forming a second release layer on a face of the second rigid support;
forming a second electrically conductive metal layer on the second release layer;
placing a second laminate made of a dielectric material comprising fibers having a resin impregnated therein over the second release layer and second conductive layer;
forming vias through the second laminate at locations overlying the electrically conductive metal layer; and
filling the vias in the second laminate with an electrically conductive filler material.

4. The process of claim 3, wherein the step of removing the rigid supports comprises removing the first rigid support from the first release layer and removing the second rigid support from the second release layer.

5. The process of claim 4, further comprising, follow the step of removing the rigid supports, a step of removing the release layers.

6. The process of claim 5, wherein the rigid supports each comprise a steel plate and the release layers each comprise a thin copper layer, and the step of removing the release layers comprises chemically etching the thin copper layers.

7. The process of claim 6, wherein the electrically conductive metal layers each comprise a sublayer of copper and a sublayer of a metal resistant to an etchant used to etch the thin copper layers, wherein the etchant-resistant metal is interposed between the copper sublayer and the thin copper release layer.

8. The process of claim 1, further comprising:
forming a third circuit pattern on at least one of the first and second laminates; and
during the bonding step, embedding the third circuit pattern between the first and second laminates.

9. The process of claim 8, wherein the third circuit pattern comprises at least one of:
an electrical conductor suitable for use as an integrated circuit power supply, and
an electrical conductor suitable for use as an integrated circuit electrical ground connection.

10. A flip-chip integrated circuit package, comprising:
a substrate including a plurality of exposed die pads on a die side of the substrate, a plurality of exposed solder ball bond pads on a ball side of the substrate, and a plurality of electrical conductors each running from a die pad to a solder ball bond pad, the conductors including elongated conductive lines extending along the substrate and interconnects extending through the substrate;
a heat sink having a central opening therein bonded to the die side of the substrate, wherein the die pads are accessible through the central opening in the heat sink;
an integrated circuit die positioned in the central opening of the heat sink in contact with the die pads; and
a layer of an encapsulant surrounding the die, wherein the layer of an encapsulant contains a heat conducting material that conducts heat from the die to the heat sink better than the encapsulant by itself.

11. The flip-chip integrated circuit package of claim 10, wherein the heat conducting material comprises metal particles distributed in the encapsulant between the die and the heat sink.

12. The flip-chip integrated circuit package of claim 10, wherein the encapsulant comprises a curable resin.
